(19) United States
(12) Patent Application Publication
(10) Pub. No.: US 2006/0110525 A1
(43) Pub. Date: May 25, 2006

(54) Nanotechnological processing to a copper oxide superconductor increasing critical transition temperature

(76) Inventor: Robert Indech, Norcross, GA (US)

Correspondence Address: Wilson Daniel Swayze, Jr., 3804 Clearwater Ct, Plano, TX, 75025, US

(21) Appl. No.: 10/994,121

(22) Filed: Nov. 19, 2004

(51) Int. Cl. B05D 5/12; C23C 16/00

(52) U.S. Cl. 427/62; 118/715

(57) ABSTRACT

A method for forming a superconductor material includes the steps of forming a substrate, placing the substrate in compressive stress, forming a hilly region on the substrate, and applying varying layering of copper, copper oxide, and selected interstitial atomic species.

### BACKGROUND

Superconductivity of materials implies the complete absence of resistance to current. Throughout the literature, the term superconductivity is just applied to direct current because all superconductor materials have some electrical resistance to alternating current. Another characteristic of superconductor material is the repulsion of an external magnetic field, called the Meissner effect. The primary reason that a superconductor material loses its superconductivity properties is 1) an applied external magnetic field is greater than a threshold field, 2) an applied current that generates an internal magnetic field is greater than a threshold flux value, and 3) an external temperature is greater than a threshold temperature. These three characteristics: external magnetic field, current flux, and temperature may be plotted along three orthogonal axes, and the resulting three dimensional surface as plotted is a phase change surface, starting from superconductive state in the interior of this mathematical representation to non-superconductive state on the exterior.

Reducing the external temperature of the subject material by going to absolute zero causes most materials become superconductive materials. The transition temperature and the date of discovery are illustrated in FIG. 1 that shows the superconductor timetable.

FIG. 1 shows the dramatic rise in the discovery of superconducting materials that occurred in the 1990's.

More particularly, some niobium compounds are extensively used because of their superconducting properties, but these niobium compounds must be cooled by liquid helium in a well-insulated configuration. The disadvantage of his type of cooling and cryogenic engineering is cost. In the late 1980's, a new class of superconductor material was discovered, termed “high-temperature”, having, as their basis, an interlaced copper-oxygen planar structure. These materials were deemed high-temperature because they could be cooled by liquid nitrogen, which is a much less expensive alternative. These superconductor materials are typically operated in the range of 80-120° Kelvin which is substantially below room temperature, requiring cryogenic engineering, but this type of cooling is not as extensive as that for the above described low-temperature superconductors.

Another type of superconductive material is the copper-oxide based superconductor that is ceramic and brittle and not easily machined. To overcome this problem, methods have been developed to embed them within hollow silver wires. In this way, the silver wires serve both as a structural support and as a method to dissipate heat should a regional portion of the ceramic lose its superconductivity properties.

The atomic structure of one of the most common high temperature superconductor yttrium-barium-copper-oxide (YBaCuO) is shown in FIG. 2 that shows the structure of YBaCuO superconductor.

The primary planes of superconductivity are along the ‘a’ axis 210 and the ‘b’ axis 212. The oxygen atom bonds at a non-180° angle with its two adjacent copper atoms. The degree of this angle is dictated by both the size and valence of the upper interstitial atom of yttrium and by the size and valance of the lower interstitial atom of barium. This unit cell configuration of yttrium, barium, copper, and oxygen, is an equilibrium configuration that is demonstrated by its conventional method of manufacture. Stochiometric amounts of copper, barium and yttrium are heated in a controlled oxygen atmosphere, typically 900° C., followed by annealing at 400-500° C., and this structure spontaneously forms. This structure then represents a lowest energy configuration of this compound. The structure is then cooled and machined or press-fit into the size desired. The essential aspect of this method of manufacture is chemical self-assembly.

It is noted from FIG. 3 that differentiates the conducting layer and the charge reservoir layer in YBaCuO showing the superconducting layer are the copper oxide planes above and below the yttrium atoms.

The oxygen-doping fraction is critical in establishing the superconducting phase, as noted in FIG. 4 that shows the oxygen doping fraction and establishment of superconductivity. At very low doping, the material shows the long-range order of an antiferromagnet. Doping breaks up the antiferromagnetic order, and the materials become insulators. Only with an oxygen doping fraction between about 0.1 and 0.2 do these materials become superconductors.

Substitution of certain other elements for the yttrium and barium, while maintaining the copper-oxide planes, also produces high-temperature superconductors, although with different critical temperatures and different critical current densities.

Characteristics of various high temperature superconductors are given in FIG. 5 that in table form shows the physical characteristics of superconductor unit cells.

The Bardeen-Cooper-Schaeffer (BCS) theory is often invoked to explain the phenomena of superconductivity. In brief, this theory notes that electrons can achieve a lower energy configuration by forming into coherent “electron trains”. This grouping of electrons can then pass through the outer electron orbitals of the material lattice and allow a resonance to appear between their travel and phonons generated by the lattice vibration. When the resonance appears, the material is superconductive. The theory notes that in superconductive materials the electron coherence length is appreciably magnified, allowing trains of electrons to pass through the bulk material without resistance. The momentum vectors of the electron train are in precise synchrony with the lattice mechanical vibration (i.e. the electron-phonon interaction).

Clearly, random vibrations of individual atoms not in phase, which define the property of raised temperature of the material, will not allow this resonance to develop and the material loses its superconductivity properties Additionally, a high external magnetic field will cause directional alignment of the outer electron orbitals, also causing loss of superconductivity. Too great a density of traveling electrons will cause an internal magnetic field, which by a similar directional alignment will also cause a loss of superconductivity. While it is accepted that BCS theory is applicable to single element low-temperature superconductors, researchers have difficulty applying it exactly to the copper-oxide based high-temperature superconductors. Thus, while considerable laboratory experimentation has been carried out in the last 20 years on these type superconductors, no theory of its mechanism has been fully accepted by the scientific community.

However, certain concepts of the BCS theory can be applied to high temperature superconductors to provide indicators to which directions to take to design the desired characteristics.

The electron is a fundamental energy wave. Impression of a small potential across an atom causes an orientation of the quantum mechanical equilibrium electron shell in the vector direction of the external electrical field. As the potential increases, an outer shell electron is released in the electric field direction and additionally an outer shell electron of an adjacent atom is absorbed to the releasing atom. Although gross electroneutrality is observed, a consequent flow of electrons occurs. If the orbital structure of the atoms is strongly coupled then no resistance to electron flow occurs. Conversely, if the outer electron orbital structures of adjacent atoms are not in phase with each other then the release or absorption of an electron will cause a shift in momentum of the atom not in synchrony with its neighboring atom. This nonsynchronous lattice vibration is heat; the electron flow thus has resistance.

An example of electron-shell hybridization for carbon is given in FIG. 6 that shows atomic orbital orientations.

While it is advantageous that YBaCuO superconductors chemically self-assemble, thus making their manufacture almost a high school chemistry exercise, there are noted disadvantages. The major disadvantage is that only certain size and valence interstitial atoms are allowed for the structure to self-assemble, even at elevated temperature. Atoms outside of a particular size and valence will not allow self-assembly, so that the non-equilibrium structure can never form. In many cases, nanotechnological material processing techniques can produce the non-equilibrium structure at an elevated temperature and then “freeze” it to room temperature. This type of processing can yield significantly different properties of the materials in question.

### SUMMARY

It has been found that specific material processing techniques will increase the critical transition temperature of copper oxide based high-temperature superconductors. An explanation of superconductivity is presented showing on parameters of the superconductor. Characteristics of the copper oxide layers of high temperature superconductors are explained including probable methods of electron-phonon coupling based on the BCS model. Variation of the Cu—O—Cu bond angle is correlated with superconductive transition temperature. An analysis of strain induced surface morphology on a nano scale is correlated with a non-equilibrium induced variation in Cu—O—Cu bond angle and in general for any acute X—Y—X bond angle. Specific manufacturing steps create such a non-equilibrium partial superconductive unit cell on a composite substrate.

### BRIEF DESCRIPTION OF THE DRAWINGS

FIG. 1 illustrates a superconductor timetable;

FIG. 2 illustrates the structure of the YBaCuO superconductor;

FIG. 3 illustrates the differentiation of conducting layer and charge reservoir in YBaCuo;

FIG. 4 illustrates a graph doping fraction and temperature;

FIG. 5 illustrates the physical characteristics of superconductor cells;

FIG. 6 illustrates atomic orbital orientations;

FIG. 7 illustrates a graph of Ion radii and atomic number;

FIG. 8 illustrates the Cu—O—Cu structure on a hilly substrate;

FIG. 9 illustrates growth mechanisms;

FIG. 10 illustrates a titanium oxide furnace;

FIG. 11 illustrates an atomic layer deposition technique;

FIG. 12 illustrates coherent strain islands;

FIG. 13 illustrates a process of layer formation;

FIG. 14 illustrates atomic layer deposition of the present invention.

FIG. 15 illustrates the method of the present invention.

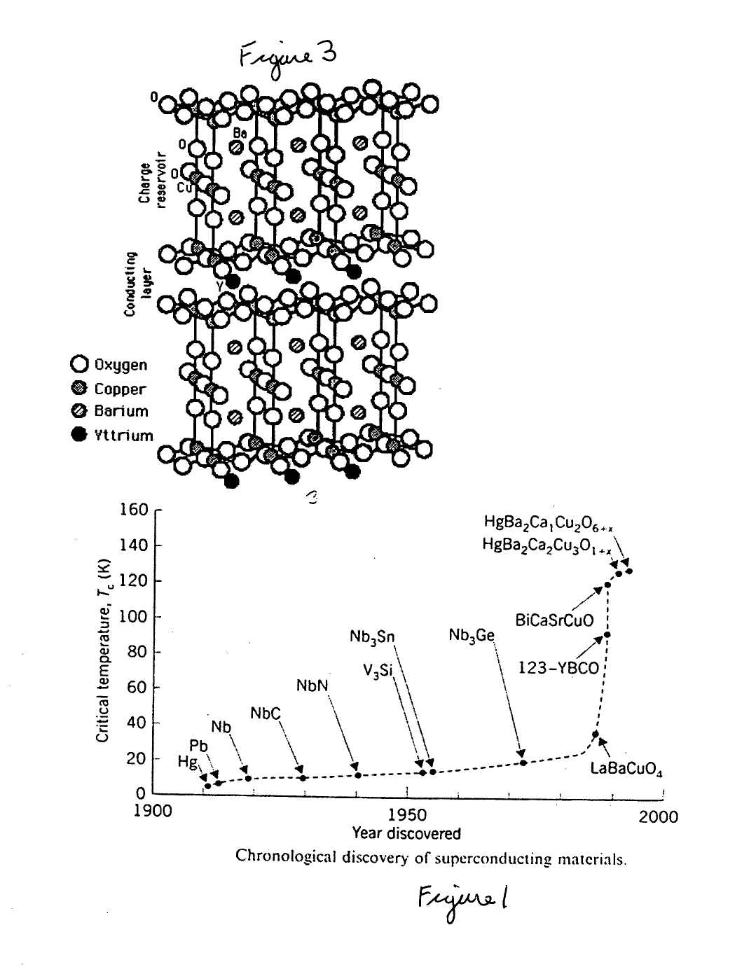

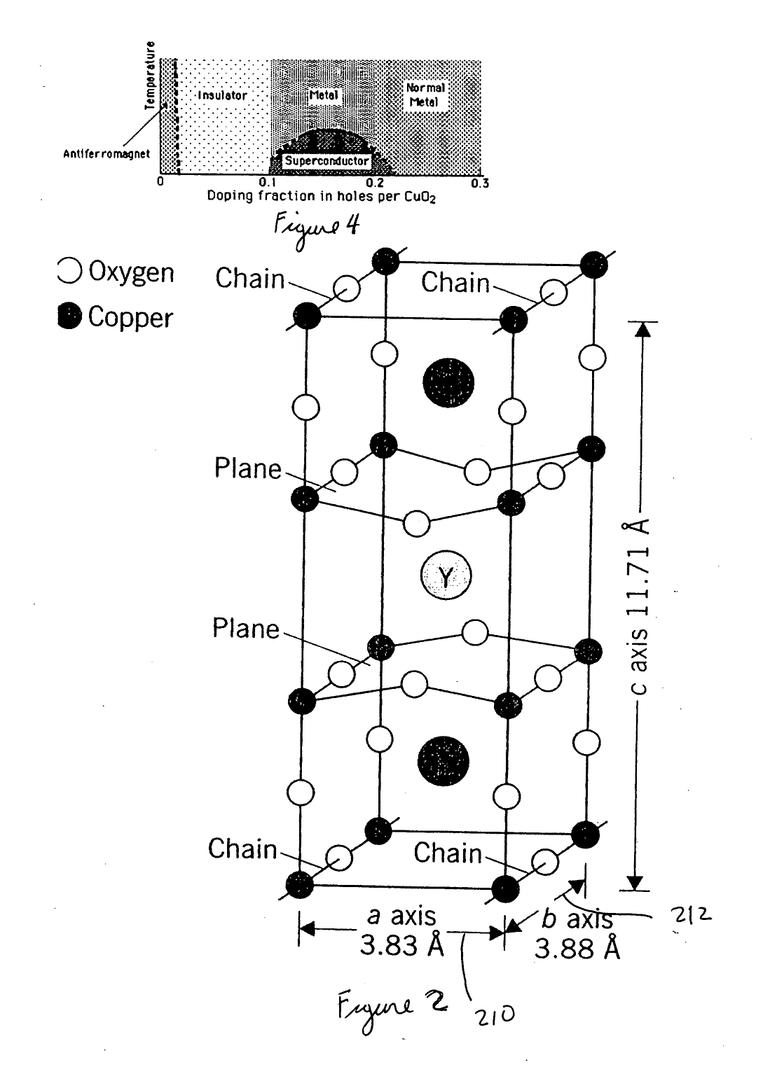

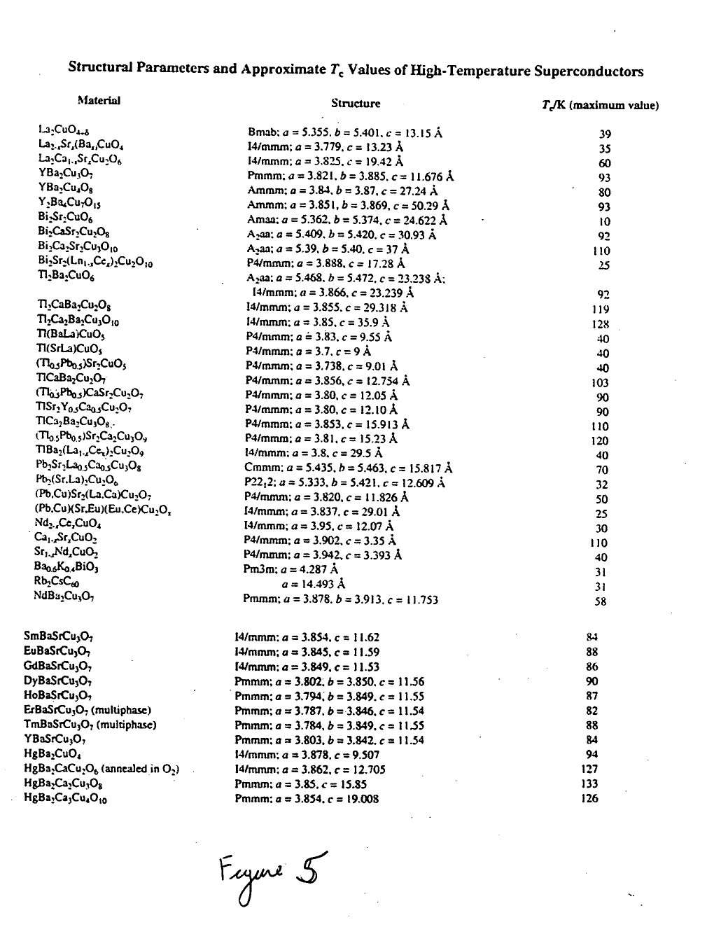

### DETAILED DESCRIPTION

III. Experimental Evidence of Variation of Critical Temperature (Tc) with Cu—O—Cu Bond Angle:

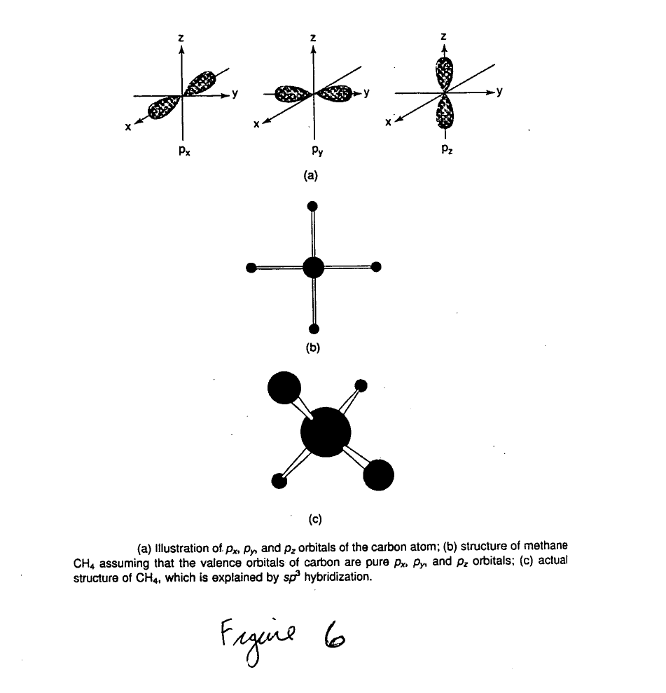

To examine the dependence of the transition temperature upon the acute Cu—O—Cu angle, consider comparisons of certain similar high temperature superconductors, as shown in FIG. 5. Note that the dimensions of the lattice parameters “a”, “b” and “c” are in angstroms.

It has been determined that reducing the Cu—O—Cu angle (i.e. making it more acute) will increase the superconductor transition temperature, all other factors being equal.

Case 1:

YBa₂Cu₃O₇, Pmmm configuration, a=3.821, b=3.885, c=11.676, Tc=93° K

and YBaSrCu₃O₇, Pmmm configuration, a=3.803, b=3.842, c=11.54, Tc=84° K

where the molecular weight of Sr is 87.62 and molecular weight of Ba is 137.33. In this case, the Cu—O—Cu angle for the Tc=84° K compound is closer to 180° than the Cu—O—Cu angle for the Tc=93° K compound.

Case 2:

TlCa₂Ba₂Cu₃O₈, a=3.856, c=15.913, Tc=110° K and HgCa₂Ba₂Cu₃O₈, a=3.85, c=15.85, Tc=133° K where the molecular weight of Hg is 200.59 and the molecular weight of Tl is 204. In this case, the Tl substitutes for the Hg. The Cu—O—Cu angle is larger for the Tl compound at Tc=110° K than for the Hg compound at Tc=133° K.

Case 3:

YBa₂Cu₃O₇, a=3.821, b=3.885, c=11.676, Tc=93° K And Tl₂CaBa₂Cu₂O₈, c=29.318 (double length of unit cell), Tc=119° K where the molecular weight of Y=88.9 and the molecular weight of Ca=40. In this case, the Ca substitutes for the Y. The Cu—O—Cu angle is more acute when the Ca is present. The second interstitial atom of barium is consistent in both compounds.

Case 4:

Ca₁₋ₓSrₓCuO₂, P4/mmm, a=3.902 Tc=110° K and SR₁₋ₓNdₓCuO₂, P4/mmm, a=3.942, Tc=40° K A direct comparison of the “a” length in the unit cell indicates that the larger length implies a less acute Cu—O—Cu angle, corresponding to a greatly reduced Tc.

To consider a possible mechanism for the observation of correlation of higher transition temperature with more acuteness of the Cu—O—Cu bond, consider the electronic configuration of copper and of oxygen. Copper, atomic number 29, has electronic configuration 1s2-2s2-2p6-3s2-3p6-3d10-4s1. Oxygen, atomic number 8, has electronic configuration 1s2-2s2-2p5. The outer electron orbitals of the oxygen are typically hybridized to sp6 configuration, with sharing at quantum number 3. Hybridization causes the oxygen to combine with other elements with an acute bond angle. This characteristic is well known in the water molecule, H₂O, wherein the molecule is not linear at all but has quite an acute bond angle. The 4s1 outer electron of the copper is loosely bound, and at room temperature typically contributes to the “sea” of electrons, making copper an excellent conductor. Thus, the copper forms 6 bonds at the outer and inner vertices of the unit cells, indicating some hybridization of the 3d10 electron shell as well.

Again, one notes that the presence of the interstitial atoms barium and yttrium cause a change in the Cu—O—Cu angle, as the compound assumes its lowest energy state at its formation temperature of about 900° K. The change in this angle indicates that the Cu—O—Cu bond is placed in stress. This increase in stress may be accompanied by an increase in the magnitude of the inter-atomic coupling constant; i.e. the molecular “spring” constant corresponding to the stiffness of the atomic bond and relating the frequency of phonon induced vibration to the magnitude of the phonon disturbance. That is, an increase in this constant will produce a decrease of amplitude of vibration for a given disturbance, much like a stiffer spring will allow lesser expansion for a given force. Thus, with a stiffer inter-atomic bonding “spring”, vibrations induced at a particular temperature are lesser in magnitude than for a looser inter-atomic bonding “spring”. Thus, if there is a certain magnitude of random vibration that causes a loss of coherency coupling between the outermost electron shells of the Cu—O—Cu—O—Cu . . . , with coincident loss of superconductivity, due to inability to have momentum coupling over very long Cu—O—Cu chain lengths, then this magnitude will be increased with a stiffer inter-atomic “spring” constant.

Substitution of different interstitial atoms will allow the control of this Cu—O—Cu angle. Increasing the atomic weight with no change in valence for a substitute for the barium atom, and decreasing the atomic weight with no change in valance for a substitute for the yttrium atom will cause a net increase in the superconductor critical temperature for the YBaCuO model. However, with narrow exceptions, the system with such substitutions may not self-assemble. Thus, different manufacturing techniques can be applied.

It is noted that the Pauling electronegativity of barium is 0.89. The covalent radius of the neutral barium atom is 1.98 Angstroms, and for compounds of barium the most common oxidation number is 2 (Positive). The electron configuration of barium in the neutral gaseous ground state is 1s2-2s2-2p6-3s2-3p6-3d10-4s2-4p6-4d10-5s2-5p6-6s2.

Further, the Pauling electronegativity of yttrium is 1.22. The covalent radius of the neutral yttrium atom is 1.62 Angstroms, and for compounds of yttrium the most common oxidation number is 3 (Positive). The electronic configuration of yttrium in the neutral gaseous ground state is 1s2-2s2-2p6-3s2-3p6-3d10-4s2-4p6-4d1-5s2.

From the above data, the barium takes up a larger volume of space in the unit cell than the yttrium, forcing the Cu—O—Cu angle to be acute about the barium, and the Cu—O—Cu angle to be obtuse about the yttrium location.

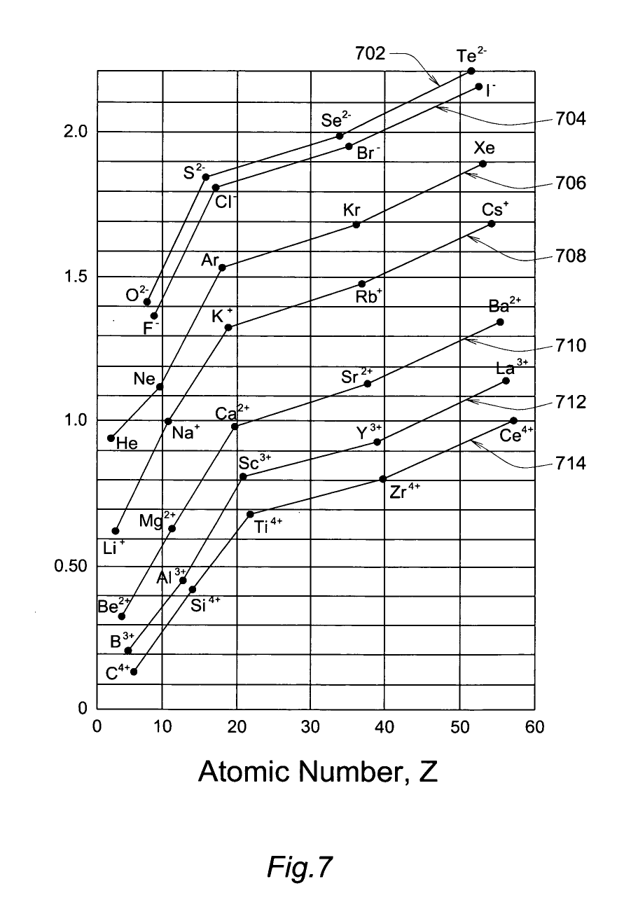

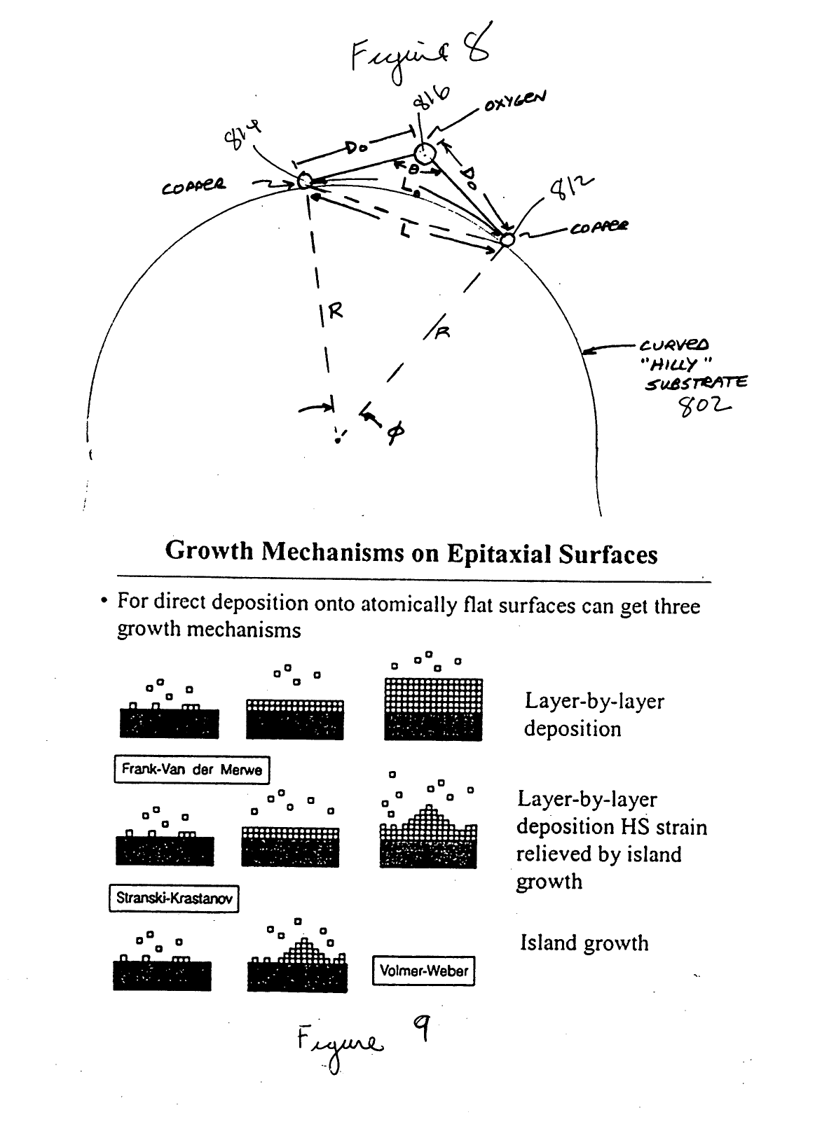

To choose a new interstitial atom for enhancement of the superconductor, a reference diagram, such as illustrated in FIG. 7, plots the ionic and atomic radii versus the atomic number in which each line connects a series of atoms or ions having the same charge. Line 702 shows elements having a charge of −2; line 704 shows elements having a charge of −1; line 706 shows elements having no charge; line 708 shows elements having a charge of +1; line 710 shows elements having a charge of +2; line 712 shows elements having a charge of +3; and line 714 shows elements having a charge of +4.

IV. Variation of Critical Current with Grain Size

Various assemblages of superconducting cells are separated from each other by grain boundaries. The crystallographic orientation of such assemblies varies markedly across the grain boundary. In general, there are two major effects acting in opposition to maximize critical current in the bulk superconductor. Increasing the size of the grain, with consequent decrease in number of grain boundaries will eventually produce the single crystal bulk superconductor and will in general tend to increase the critical current. By eliminating the grain boundary, there is an easier coupling of the electrons into the “wave train” necessary for superconductivity (per BCS theory). The interaction of the electron train with lattice phonons is better controlled in the single crystal bulk superconductor. However, there is a second major effect that simultaneously occurs. The placement of an external magnetic field close to the superconductor, and in addition, the creation of internal magnetic fields in the superconductor due to current transport will create small superconducting vortices at the surface of the superconductor, extending downward from the surface to approximately the London penetration depth. These vortices also travel in the plane of the surface of the superconductor. Grain boundaries tend to slow down the travel of these superconductive vortices and tend to pin them in place. This phenomenon is called “flux pinning”. The greater the degree of flux pinning then the higher the critical transition current. Thus, there appears to be a critical grain size that would maximize the critical current, above and below which the critical current would decrease. For YBaCuO superconductors, this critical grain size is in the tens of nanometer range. To control the grain size to be at this optimal value, one would first fabricate the superconductor as a powder. Then one would employ a number of known nanotechnological materials processing techniques, such as attrition milling/grinding, rolling of the material under high pressure, exposing surfaces to friction-induced wear conditions, and severe plastic deformation via equi-channel angular extrusion.

V. Approach to Increasing Critical Temperature

In one method of manufacturing of high temperature superconductors, the necessary ingredients are placed in the correct stochiometric ratios in a container, the container is then heated to a temperature in which the materials are in the liquid or gaseous phases, and the resulting mixture is then allowed to chemically self-assemble into the desired molecular configuration. This particular configuration is that specific placement of atoms that will minimize the Gibbs free energy of the mixture. Thus, the molecular arrangement is an equilibrium arrangement. The system is then cooled, essentially “freezing” the configuration in place. Sufficient time for equilibrium atomic placement must be allowed, as the system is invariably not well mixed, and thus, critical components of the final arrangement must be allowed to diffuse into their correct places. The diffusion distance is an increasing function of increasing time, and an increasing function of increasing temperature. However, there is an upper bound to the temperature, as the entropy of the system increases with temperature, which will increase the Gibbs free energy. The entropy of the system decreases with formation of the ordered unit cells. Thus, again, there is an optimal temperature and an optimal time at that temperature for the unit cells to form. Unfortunately, particularly when the unit cells rely upon interstitial atoms for proper composition and spacing of the atoms around the lattice, the size and valance of these interstitial atoms are limited by their ability to minimize the Gibbs free energy of the compound as a whole at the formation temperature. Thus, not just any interstitial atoms will do; certain interstitial atoms may not allow the desired compound to form at all. Thus, while some variability of interstitial atoms is allowed, this variability is limited.

As it is noted before, there is a correlation between the Cu—O—Cu bond angle and the critical temperature. When formed, there are essentially no forces at this elevated equilibrium temperature that will force the bond angle to significantly change from its free-space value. That is, high temperature formation alone will not create sufficient strain in the Cu—O—Cu bond angle to allow a critical superconductive temperature in the range that we require, 300-400 degrees Kelvin.

It is noted that the formation of the superconductor unit cells occur in bulk; the entire mixture forms the superconductor at once, with 10²⁰ unit cells forming simultaneously. As such the pressure in the formation vessel is approximately isotropic.

Consider a method to create a non-isotropic formation. In this method, we first analyze the variation of any X—Y—X acute bond angle when fabricated upon an uneven “hilly” substrate.

VI. Mathematical Solution of Variation of Bond Angle With a Hilly Substrate

FIG. 8 shows the growth mechanisms on epitaxial surfaces. Consider for any 2 types of atoms described here as X and Y atoms that the equilibrium distance between the two X atoms in the X—Y—X bond is denoted by “L”. For the embodiment of the Cu—O—Cu system, L is approximately 3.8 Angstroms. Referring to FIG. 8, a hilly substrate 802 with a radius of curvature that is a low multiplicative factor of this noted equilibrium distance is created. The atoms 812, 814 denoted as “X” are respectively strongly bonded to atom 816 denoted as “Y”. Further, the atoms of the substrate 802 are attractive to the atoms 812, 814, so that a net force is exerted on the atoms 812, 814, causing the atoms 812, 814 to place themselves in close proximity to the surface atoms of the substrate 802. The inter-atomic spacing of the surface atoms of the substrate 802 is set below the bulk equilibrium “L” length; the resultant effect being that the X—Y—X bond angle will decrease.

Define the X—Y—X bond angle as “θ” and the equilibrium X—Y—X bond angle as “θₒ.”. Define the X-X separation distance as “L” and the equilibrium X-X separation distance as “Lₒ”. Define the equilibrium X—Y separation distance as “Dₒ”. Define the radius of curvature of the hilly substrate 802 as “R”. Define the angle subtended by the hilly substrate 802 between the points of contact of X-X on its surface as “φ”. Assuming tight attraction of the X atoms to the substrate atoms, then the effect of substrate curvature will be to decrease “L”. With tight attraction, we then can specify “Lₒ” as the arc length of the curved surface between adjacent X atoms. Clearly, as the radius of substrate curvature decreases then the X-X separation distance, “L”, decreases as well. Mathematically, equation (1) relates the equilibrium X—Y—X variables:
(Lₒ)²=2(Dₒ)²×(1−cos θₒ) Eqn (1)
and equation (2) relates the current X—Y—X geometry:
L²=2(Dₒ)²×(1−cos θ) Eqn (2)

Relations between the hilly substrate and X—X bond lengths and angles are equations (3) and (4).
R×φ=Lₒ Eqn (3)
L²=2R²×(1−cos φ) Eqn (4)

These four equations are now simultaneously solved to find the change in bond angle (θₒ−θ) as a function of the other variables. After some mathematics, the solution is equation (5):
(θₒ−θ)=θₒ−cos⁻¹(1−(1−cos θₒ)×(2R²/Lₒ²)×(1−cos(Lₒ/R))
or (θₒ−θ)=θₒ−cos⁻¹(1−(R²/Dₒ²)×(1−cos(Lₒ/R))

As a numerical example, suppose that θₒ=120°, θ=118°, and Lₒ=5 Angstroms, then computation yields R=1.01 nM, and φ=28.7°. For a sinusoidal hilly substrate, the hill arc length is 1.01 nM×(180/28.7)=6.3 nM, and the hill width is 2×1.01 nM=2.02 nM. Thus, a hilly substrate 802 may allow some control of value of the X—Y—X bond angle, with deviation from its bulk equilibrium value.

VII. Manufacturing Techniques to Increase Critical Temperature

To increase critical temperature, one may utilize a top-down nano-technological manufacturing approach, coupled with self-assembly principles.

Three growth mechanisms for direct deposition of atoms onto an atomically flat surface are shown in FIG. 9: layer-by-layer deposition, layer-by-layer deposition under strain relieved by island growth, and direct island growth, as shown in FIG. 9.

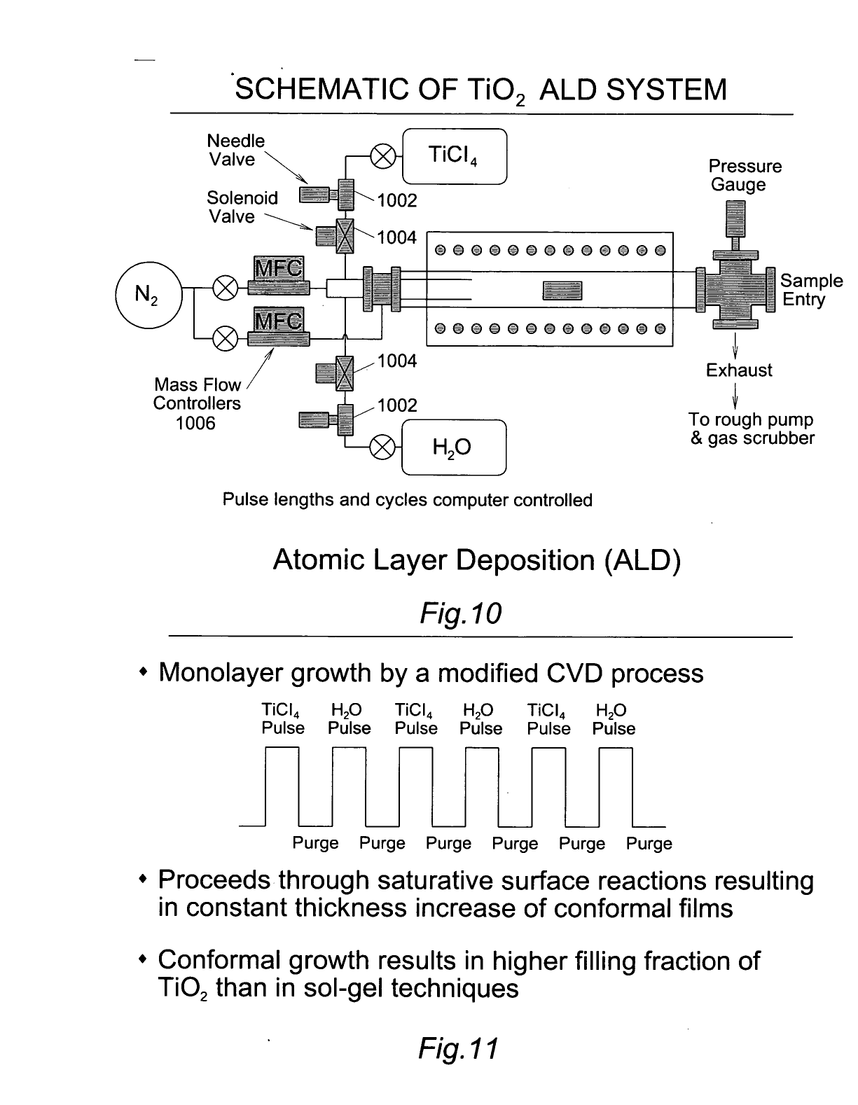

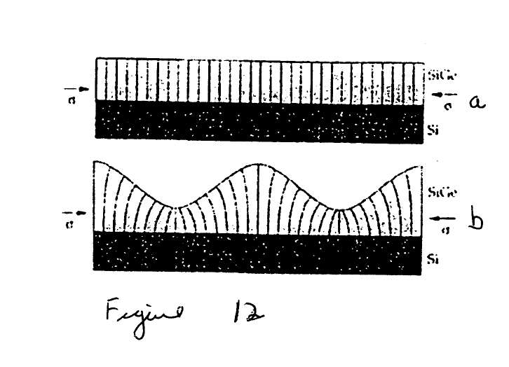

The general technique of deposition involves placing the atomic species desired to be deposited into the gaseous state, depositing the atomic species upon a substrate under controlled time and temperature conditions, then purging the system with vacuum or an inert gas and allowing a different atomic species to then deposit, and repeating the process until the layer is built up to the thickness desired. This is illustrated for the titanium oxide atomic layer deposition system in FIGS. 10 and 11. FIG. 11 shows the sequence of depositing TiCl₄, purging with N₂, depositing H₂O, and purging with N₂ etc. FIG. 10 shows that the amount of TiCl₄ and H₂O is controlled by needle valve 1002 and the duration is controlled by solenoid valve 1004. The mass flow controller 1006 controls the flow of N₂.

A technique in nano-technological manufacturing is strain-induced growth. In this technique, the composite substrate is placed under compressive stress. Normally, elastic strain energy is relieved by misfit dislocations. In the special cases of 2 to 5 monolayers of the upper species of the composite, below a critical thickness, these dislocations do not occur. Rather, coherently strained islands do occur in a composite structure. This effect is illustrated in FIG. 12.

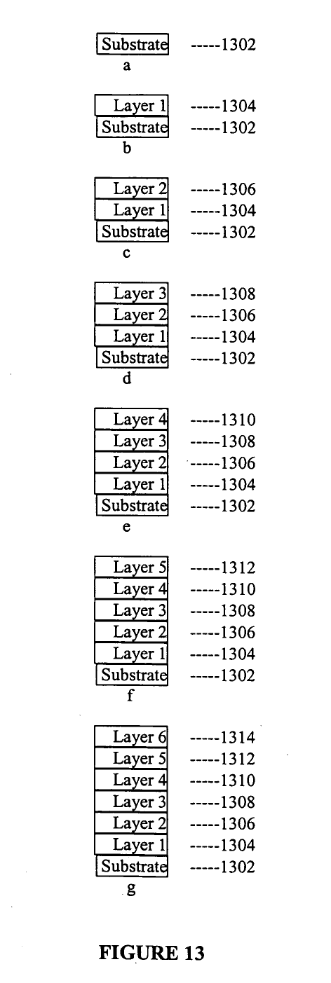

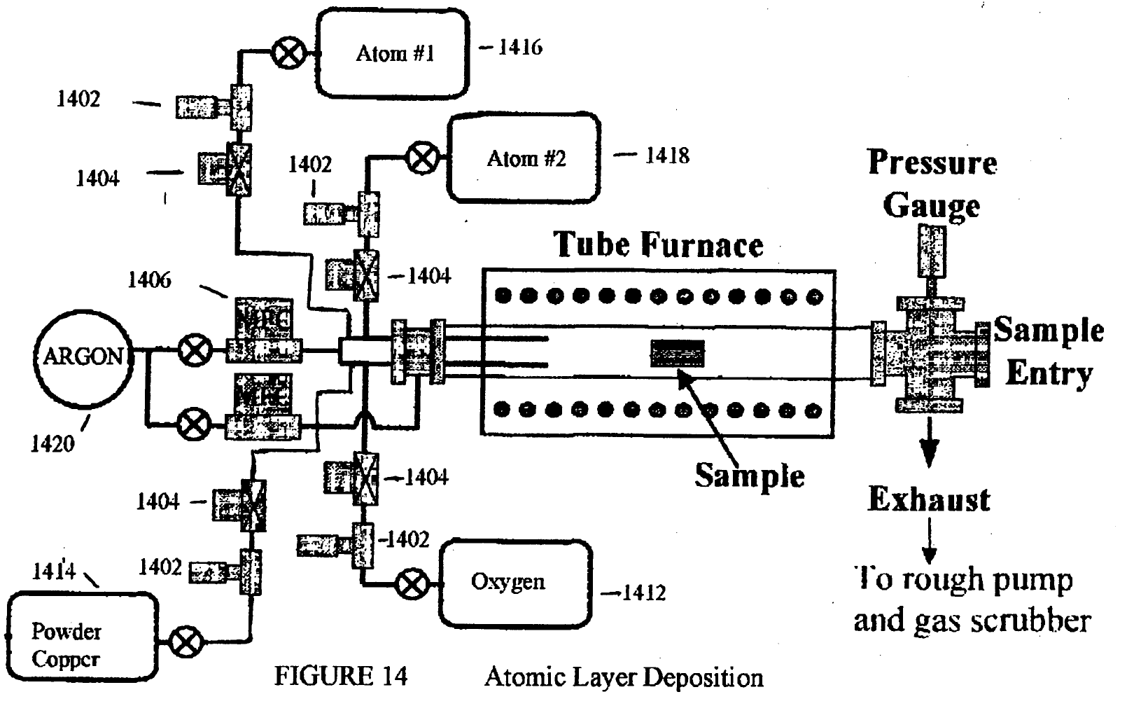

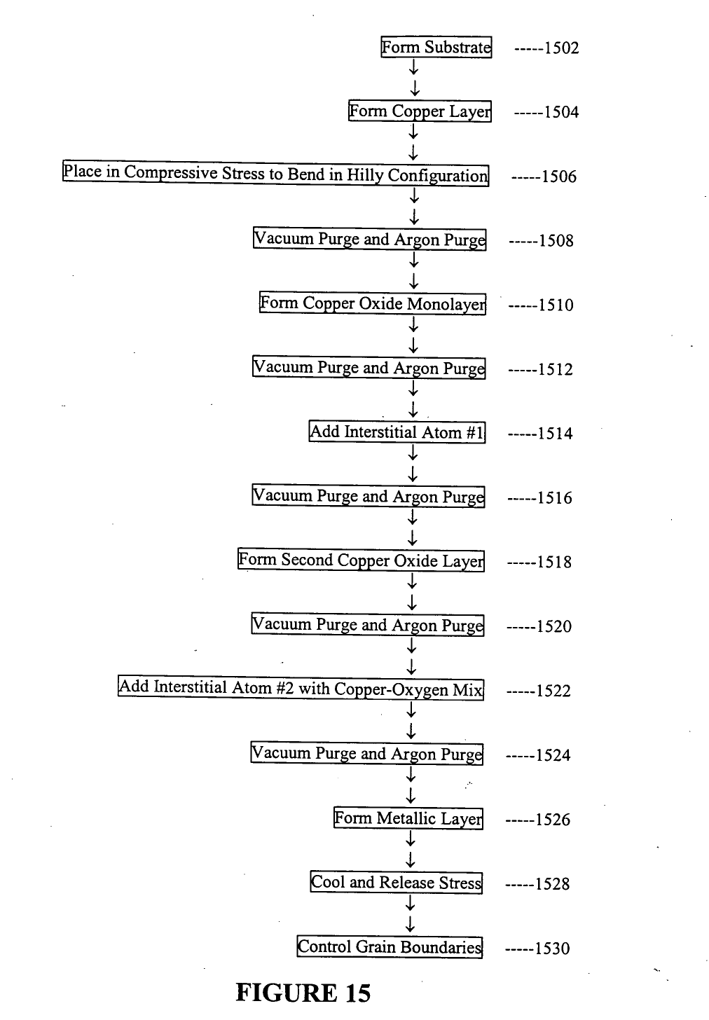

To apply these techniques to the YBaCuO model, first produce by nanotechnological techniques, a composite atomically flat substrate not under mechanical stress, composed of a single material, as illustrated in FIG. 13a, as in step 1502. Two to five monolayers of copper are deposited on the substrate in a vacuum, as in step 1504, in an ALD system such as the one illustrated in FIG. 14, but with chemical reservoirs of oxygen 1412, powdered copper 1414, selected powdered interstitial atom #1 1416, selected powdered interstitial atom #2 1418, and inert gas argon purge gas 1420, each of being controlled by a needle valve 1402 and solenoid valve 1404 except the purge being controlled by the mass flow controller 1406. The substrate 1302, 1304 is placed in compressive stress as in step 1506. The copper substrate layer 1304 is thus reconfigured into a hilly form as shown in FIG. 13b. This creates alternating regions of positive convex arcs and negative concave arcs, as viewed from its side as shown in FIG. 12b.

A hilly composite substrate is formed in step 1506. Remaining nonbound copper atoms are then purged from the system in step 1508. A monolayer of copper is then deposited on the substrate in a depleted oxygen environment, in an ALD system such as the one illustrated in FIG. 14 forming a copper oxide layer 1306 as shown in FIG. 13c on the composite substrate 1304 as shown in FIG. 13b and as step 1510. Due to the attraction of the Cu—O—Cu structure to the hilly copper layer 1304, the top layer of the composite substrate, the Cu—O—Cu bonds will align, preferably in an acute angle when viewed from the side with the substrate at the base. The concave arc has the effect of causing an increase in the Cu—O—Cu angle, while the convex arc will cause a decrease in the Cu—O—Cu angle, as mathematically calculated above. The system is purged of excess copper and oxygen through vacuum pump, followed by an inert gas purge such as an argon purge cycle as in step 1512, and an interstitial atom #1 species 1416 is then introduced as in step 1614. This species 1416 may be selected as scandium or aluminum, both characterized by similar electronegativity and valences to yttrium, but with smaller atomic diameter. After deposition of the interstitial atoms as an atomic monolayer 1308 as shown in FIG. 13d, through time-temperature controls, the system is then purged through vacuum pump followed by an inert gas purge such as argon purge cycle as in step 1516. Another layer of copper in depleted oxygen atmosphere is now deposited to form the second copper-oxide layer 1310 as shown in FIG. 13e, as shown in step 1518. The system is then purged through vacuum pump followed by an inert gas purge such as argon system purge as in step 1520.

Now, the next portion of the unit cell is constructed. The interstitial atom #2 species 1418 may be barium or another species of greater atomic weight (and hence atomic diameter) than barium, but with similar electronegativity and valence. One might use tungsten, platinum, lead, mercury or bismuth equally well. Barium may be used, as it forms the known portion of the superconductive cell, if the substituted atom for the yttrium is sufficient to bring the transition temperature up to the value desired. The larger the atomic radius of interstitial atom #2 1418, the more difficult it will be to subsequently form the subsequent copper-oxide layer of the unit cell. Interstitial atom #2 1418 is deposited in a stochiometric copper-oxygen mix, which mix self-assembles into the next part of the superconductive matrix around this atom #2 1418 and using the built up copper-oxide layer 1310 as its substrate to form layer 1312 as shown in FIG. 13f, as in step 1522. The system is purged through vacuum pump and argon system purge as in step 1524. At this point, the essence of the unit superconductive cell has been deposited. A thick metallic layer 1314 may then be deposited for electrical connection, mechanical and thermal stabilization, as shown in FIG. 13g, as in step 1526. It is not contemplated to remove the original composite substrate from the copper-oxide layer. The more acute Cu—O—Cu bond angle section will correspond to the higher superconductive temperature section that will alternate with a lower superconductive temperature section. Using modern production techniques, the hilly portion 802 of the substrate may extend to millions of atoms in a straight line along the plane of the surface, leading to a macroscopic quantity of very high temperature superconductor.

The system is still under compressive stress. The system is cooled and the compressive stress is released as in step 1528, although the hilly structure remains. The final material is thus a single microscopic unit cell layer built upon a substrate, as a large single crystal. The material could then be further processed as noted above in the section on manufacturing techniques to control grain boundaries as in step 1530. By making more acute the Cu—O—Cu bond angle the superconductive transition temperature is increased manifold, the exact final transition temperature dependent on the bond angle reduction.

1) A method for forming a superconductor material, comprising the steps of:
forming a substrate;
placing said substrate in compressive stress;
forming a hilly region on said substrate.

2) A method for forming a superconductor material as in claim 1 wherein said hilly region includes a convex region and a concave region.

3) A method for forming a superconductor material as in claim 1, wherein said method includes the step of forming copper-oxygen-copper bonds on said hilly region.

4) A method for forming a superconductor material as in claim 1, wherein said method includes the step of applying tensile stress to said substrate.

5) A method for forming a superconductor material as in claim 1, wherein said method includes the step of applying a copper-oxygen mix to said hilly region.

6) A method for forming a superconductor material as in claim 1, wherein said method includes the step of forming a copper layer on said substrate before said compressive stress is applied.

7) A method for forming a superconductor material as in claim 5, wherein said method includes the step of depositing a first interstitial atomic species upon said copper-oxide layer.

8) A method for forming a superconductor material as in claim 7, wherein said method includes the step of depositing a second copper-oxide layer.

9) A method for forming a superconductor material as in claim 8, wherein said method includes the step of depositing a second interstitial atomic species and a third copper-oxide layer upon said second copper-oxide layer.

10) A method for forming a superconductor material as in claim 1, wherein said method includes the step of releasing compressive stress of said substrate.

11) An apparatus forming a superconductor material, comprising an atomic layer deposition apparatus to deposit a substrate; said atomic layer deposition apparatus applying compressive stress to said substrate; and
said atomic layer deposition apparatus forming a hilly region on said substrate.

12) An apparatus for forming a superconductor material as in claim 11 wherein said hilly region includes a convex region and a concave region.

13) An apparatus for forming a superconductor material as in claim 11, wherein said atomic layer deposition apparatus forms copper-oxygen-copper bonds on said hilly region.

14) An apparatus for forming a superconductor material as in claim 11, wherein said atomic layer deposition apparatus applies tensile stress to said substrate.

15) An apparatus for forming a superconductor material as in claim 11, wherein said atomic layer deposition apparatus applies a copper-oxygen mix to said hilly region.

16) An apparatus for forming a superconductor material as in claim 11, wherein said atomic layer deposition apparatus forms a copper layer on said substrate before said compressive stress is applied.

17) An apparatus for forming a superconductor material as in claim 11, wherein said atomic layer deposition apparatus applies a vacuum purge followed by an argon purge.

18) An apparatus for forming a superconductor material as in claim 10, wherein said atomic layer deposition apparatus applies multiple interstitial atomic layers and multiple copper oxide layers on said substrate.

19) An apparatus for forming a superconductor material as in claim 11 wherein said atomic layer deposition apparatus releases said compressive stress of said substrate.

20) An apparatus for forming a superconductor material as in claim 14, wherein said atomic layer deposition apparatus releases said tensile stress of said substrate.
